(19) United States
(12) Patent Application Publication
(10) Pub. No.: US 2010/0290968 A1
(43) Pub. Date: Nov. 18, 2010

(54) SOLUTION BASED LANTHANIDE AND GROUP III PRECURSORS FOR ATOMIC LAYER DEPOSITION

(76) Inventors: Ce MA, San Diego, CA (US); Kee-Chan Kim, Carlsbad, CA (US); Graham Anthony McFarlane, Carlsbad, CA (US)

Correspondence Address: The BOC Group, Inc., 575 MOUNTAIN AVENUE, MURRAY HILL, NJ, 07974-2082, US

(21) Appl. No.: 12/465,094

(22) Filed: May 13, 2009

(51) Int. Cl. C01F 17/00; C07F 5/00; C07F 5/06; H01L 21/316; B05D 5/12

(52) U.S. Cl. 423/263; 534/15; 556/170; 106/287.17; 106/287.18; 427/126.3

(57) ABSTRACT

Oxygen free cyclopentadienyl solvent based precursor formulations having the general formula:

(R₁R₂R₃R₄R₅Cp)₃*M

wherein R₁, R₂, R₃, R₄, and R₅ are H or hydrocarbon CₙHₘ (n=1 to 10, m=1 to 2n+1), Cp is cyclopentadienyl and M is an element from the lanthanide series or Group III materials.

### RELATED APPLICATIONS

The solution based ALD precursors of the present invention are related to other work carried out by the inventors and assignee of this application. In particular, U.S. Ser. No. 11/400,904 relates to methods and apparatus of using solution based precursors for ALD. U.S. Ser. No. 12/396,806 relates to methods and apparatus of using solution based precursors for ALD. U.S. Ser. No. 12/373,913 relates to methods of using solution based precursors for ALD. U.S. Ser. No. 12/374,066 relates to methods and apparatus for the vaporization and delivery of solution based precursors for ALD. U.S. Ser. No. 12/261,169 relates to solution based lanthanum precursors for ALD.

### FIELD OF THE INVENTION

The present invention relates to new and useful solution based precursors for atomic layer deposition.

### BACKGROUND OF THE INVENTION

Atomic layer deposition (ALD) is an enabling technology for advanced thin-film deposition, offering exceptional thickness control and step coverage. In addition, ALD is an enabling technique that will provide the next generation conductor barrier layers, high-k gate dielectric layers, high-k capacitance layers, capping layers, and metallic gate electrodes in silicon wafer processes. ALD-grown high-k and metal gate layers have shown advantages over physical vapor deposition and chemical vapor deposition processes. ALD has also been applied in other electronics industries, such as flat panel display, compound semiconductor, magnetic and optical storage, solar cell, nanotechnology and nanomaterials. ALD is used to build ultra thin and highly conformal layers of metal, oxide, nitride, and others one monolayer at a time in a cyclic deposition process. Oxides and nitrides of many main group metal elements and transition metal elements, such as aluminum, titanium, zirconium, hafnium, and tantalum, have been produced by ALD processes using oxidation or nitridation reactions. Pure metallic layers, such as Ru, Cu, Ta, and others may also be deposited using ALD processes through reduction or combustion reactions.

The widespread adoption of ALD processes faces challenges in terms of a restricted selection of suitable precursors, low wafer throughput, and low chemical utilization. Many ALD precursors useful in HKMG exist in the solid phase with relatively low volatility. To meet these challenges, the present invention develops a solution-precursor-based ALD technology called Flex-ALD™. With solution-based precursor technology, ALD precursor selection is considerably broadened to include low-volatility solid precursors, wafer throughput is increased with higher film growth rates, and chemical utilization is improved via the use of dilute chemistries. In addition, liquid injection with vapor pulses provides consistent precursor dosage.

A typical ALD process uses sequential precursor gas pulses to deposit a film one layer at a time. In particular, a first precursor gas is introduced into a process chamber and produces a monolayer by reaction at surface of a substrate in the chamber. A second precursor is then introduced to react with the first precursor and form a monolayer of film made up of components of both the first precursor and second precursor, on the substrate. Each pair of pulses (one cycle) produces one monolayer or less of film allowing for very accurate control of the final film thickness based on the number of deposition cycles performed.

As semiconductor devices continue to get more densely packed with devices, channel lengths also have to be made smaller and smaller. For future electronic device technologies, it will be necessary to replace SiO₂ and SiON gate dielectrics with ultra thin high-k oxides having effective oxide thickness (EOT) less than 1.5 nm. Preferably, high-k materials should have high band gaps and band offsets, high k values, good stability on silicon, minimal SiO₂ interface layer, and high quality interfaces on substrates. Amorphous or high crystalline temperature films are also desirable.

Lanthanide and Group III based materials are promising high-k dielectric materials for advanced silicon CMOS, germanium CMOS, and III-V transistor devices. The lanthanide and Group m based materials have relatively high dielectric constants (20-40) and exhibit good interfacial properties with high mobility channels in transistors. Metal oxides can be used as memory capacitance materials in the 32 nm DRAM technology node and beyond.

The lanthanides include lanthanum, cerium, praseodymium, neodymium, samarium, europium, gadolinium, terbium, dysprosium holmium, erbium, thulium, ytterbium, and lutetium, and are part of the Group III elements that further include scandium and yttrium. Atomic layer deposition (ALD) is the preferred method for depositing ultra thin layers of lanthanides and Group III materials that include metals, metal oxides and metal nitrides. However, ALD precursors for these compounds are not readily available and those that do exist are difficult to use because of low volatility and low thermal stability.

There remains a need in the art for improvements to lanthanide and Group III precursors for use in ALD processes.

### SUMMARY OF THE PRESENT INVENTION

The present invention provides improved solvent based precursor formulations. In particular, the present invention provides oxygen free cyclopentadienyl (Cp) precursors having the general monomer formula:

(R₁R₂R₃R₄R₅Cp)₃*M

wherein R₁, R₂, R₃, R₄, and R₅ are H or hydrocarbon CₙHₘ (n=1 to 10, m=1 to 2n+1) Cp is cyclopentadienyl and M is an element from the lanthanide series or Group III materials.

### DETAILED DESCRIPTION OF THE INVENTION

The present invention provides solvent based oxygen free cyclopentadienyl (Cp) precursors having the general monomer formula:

(R₁R₂R₃R₄R₅Cp)₃*M

wherein R₁, R₂, R₃, R₄, and R₅ are H or hydrocarbon CₙHₘ (n=1 to 10, m=1 to 2n+1), Cp is cyclopentadienyl and M is an element from the lanthanide series or Group III materials.

Solvents for the precursor formulations of the present invention include alkanes, alkenes, alkynes, amides, acetates, ethers, esters and other hydrocarbons or mixtures thereof. Oxygen free solvents or mixtures are preferred.

In accordance with the present invention MyOx thin ALD films can be formed from a starting metal precursor of 0.01M to 0.5M (EtCp)₃M, where M is an element from the lanthanide or Group III series, dissolved in n-octane or other alkane solvent, and an oxygen precursor of water vapor, and y and x are from 1 to 3. In particular, a Gd₂O₃ thin ALD film may be formed from a starting metal precursor of 0.01M to 0.5M (EtCp)₃Gd dissolved in n-octane or other alkane solvent, and water vapor.

Further in accordance with the present invention, MyOx thin ALD films can be formed from a starting metal precursor of 0.01M to 0.5M (iPrCp)₃M or (nPrCp)₃M, where M is an element from the lanthanide or Group III series, dissolved in n-octane or other alkane solvent, and an oxygen precursor of water vapor. In particular, a La₂O₃ thin ALD film can be formed from a starting metal precursor of 0.01M to 0.5M (iPrCp)₃La dissolved in n-octane or other alkane solvent, and an oxygen precursor of water vapor.

Another example of the present invention provides for the formation of MyOx thin ALD films formed from a starting metal precursor of 0.01M to 0.5M (tBuCp)₃M or (BuCp)₃M, where M is an element from the lanthanide or Group III series, dissolved in n-octane or other alkane solvent, and an oxygen precursor of water vapor.

Other embodiments of the present invention use different alkanes as the solvent for the solid precursor materials. In particular alkane solvents can be linear, branched or cyclic in form with the number of carbon atoms being from 2 to 20. Such solvents can be chosen to match solubility, transport and phase properties of the metal component of the precursor.

The oxygen precursor can be water vapor as noted above, but can also be other oxygen containing reactants, such as O₂, O₃, N₂O, NO, CO, CO₂, CH₃OH, C₂H₅OH, other alcohols, other acids and oxidants. Alternatively, nitride films can be produced according to the present invention by using a nitrogen containing reactant such as NH₃, N₂H₄, amines, etc. Similarly, metal ALD films can be formed by using hydrogen, hydrogen atoms or other reducing agents as the second precursor.

The solution based precursor of the present invention are dissolved in a suitable solvent and then delivered at room temperature to a point-of-use vaporizer by a direct liquid injection method. The vaporizer temperature is set between 50° C. and 250° C. The fully vaporized solution precursors are then pulsed into a deposition chamber in ideal square wave forms for ALD growth. By pulsing in such a fashion, there is no overlap between metal precursor pulses and the other reactant pulses, for pulses from 1 to 10 seconds. By separating the metal and other reactant in time and space according to the present invention, true ALD film growth is obtained.

For formation of Gd₂O₃ thin ALD film from a starting metal precursor of (EtCp)₃Gd dissolved in n-octane or other alkane solvent, preferred vaporizer temperature is 140° C. to 180° C. and most preferably 150° C. to 160° C., and preferred deposition temperature is 150° C. to 200° C. and most preferably 150° C. This resulted in ALD growth without unreacted precursor or residue in the vaporizer. The film growth is highly self limited and no carbon impurity was found in the grown film. Care must be taken to avoid contamination as the precursor is highly sensitive to impurities. Some experimental results using (EtCp)₃Gd as the precursor material are provided in Table 1.

TABLE 1
Experimental Results Using (EtCp)₃Gd Precursor Material

| Vaporizer | | | Unreacted | |
|---|---|---|---|---|
| Temp. | Deposition | Conc. | precursor residue | |
| (° C.) | Temp. (° C.) | (M) | in vaporizer | Results |
| 160 | 150 | 0.05 | No residue | ALD growth |
| 160 | 160 | 0.05 | No residue | ALD + small CVD |
| 180 | 180 | 0.05 | No residue | ALD + CVD |

The present invention includes many lanthanum or Group III material metal precursors for ALD growth, including for example, Gd(EtCp)₃, La(iPrCp)₃, Lu(iPrCp)₃, Sc(iPrCp)₃, Sc(nPrCp)₃, Gd(iPrCp)₃.

Other solvents and additives may be included in the precursor solution of the present invention. These solvents and additives must not interfere with the ALD process either in the gas phase or on the substrate surface. In addition, the solvents and additives should be thermally robust without any decomposition at ALD processing temperatures. Hydrocarbons are preferred as primary solvents to dissolve ALD precursors by means of agitation or ultrasonic mixing if necessary. Hydrocarbons are chemically inert and compatible with the precursors and do not compete with the precursors for reaction sites on the substrate surface. The boiling point of the solvents should be high enough to match the volatility of the solute in order to avoid particle generation during the vaporization process.

The precursors of the present invention provide several advantages, including being able to employ solid precursors for liquid solution based ALD processes. By using such chemistries, a low thermal budget room temperature delivery is possible and thereby overcomes thermal decomposition problems associated with standard liquid precursors. The process enabled by the precursors of the present invention is environmentally friendly as such process requires less metal precursor in the solution systems. The present invention expands the usability of solid precursors that could not otherwise be easily used in ALD processes. The solution precursors of the present invention allow for the ALD film growth by complete vaporization of the precursor and other reactant.

The precursors of the present invention are useful for several applications. In particular, the precursors of the present invention may be used for forming high-k gate dielectric layers for Si, Ge, and C based group IV elemental semiconductors or for forming high-k gate dielectric layers for InGaAs, AlGaAs and other III-V high electron mobility semiconductors. In addition, the precursors of the present invention are useful for forming high-k capacitors for DRAM, flash and ferroelectric memory devices. The precursors of the present invention can also be used as active surfaces for gas purification, organic synthesis, fuel cell membranes and chemical detectors, and in photoelectronic applications, such as laser, light amplification, light transportation, light emission, and light detection.

It is anticipated that other embodiments and variations of the present invention will become readily apparent to the skilled artisan in the light of the foregoing description, and it is intended that such embodiments and variations likewise be included within the scope of the invention as set out in the appended claims.

What is claimed:

1. A precursor for atomic layer deposition having the general formula:
(R₁R₂R₃R₄R₅Cp)₃*M
wherein R₁, R₂, R₃, R₄, and R₅ are H or a hydrocarbon having the formula CₙHₘ, wherein n=1 to 10 and m=1 to 2n+1, Cp is cyclopentadienyl and M is a lanthanide or Group III element.

2. The precursor of claim 1 comprising 0.01M to 0.5M (EtCp)₃M, where M is a lanthanide or Group III element, dissolved in a solvent.

3. The precursor of claim 2 wherein the solvent is an alkane, alkene, alkyne, amide, acetate, ether, ester, a hydrocarbon, or mixtures thereof.

4. The precursor of claim 3 wherein this solvent is oxygen free.

5. The precursor of claim 3 wherein the solvent is a linear, branched or cyclic alkane having 2 to 20 carbon atoms.

6. The precursor of claim 2 comprising 0.01M to 0.5M (EtCp)₃Gd dissolved in an alkane solvent.

7. The precursor of claim 6 wherein the solvent is n-octane.

8. The precursor of claim 1 comprising 0.01M to 0.5M (iPrCp)₃M, where M is a lanthanide or Group III element, dissolved in a solvent.

9. The precursor of claim 8 comprising 0.01M to 0.5M (iPrCp)₃La dissolved in an alkane solvent.

10. The precursor of claim 1 comprising 0.01M to 0.5M (tBuCp)₃M, where M is a lanthanide or Group III element, dissolved in a solvent.

11. An MyOx film wherein M is a lanthanide or Group III element and y and x are from 1 to 3, deposited by atomic layer deposition using a precursor comprising (EtCp)₃M, where M is a lanthanide or Group III element and Cp is cyclopentadienyl.

12. The film of claim 11 wherein M is Gd, the precursor is (EtCp)₃Gd, and the film is Gd₂O₃.

13. An MyOx film wherein M is a lanthanide or Group III element and y and x are from 1 to 3, deposited by atomic layer deposition using a precursor comprising (iPrCp)₃M or (nPrCp)₃M, where M is a lanthanide or Group III element and Cp is cyclopentadienyl.

14. The film of claim 13 wherein M is La, the precursor is (iPrCp)₃La, and the film is La₂O₃.

15. An MyOx film wherein M is a lanthanide or Group III element and y and x are from 1 to 3, deposited by atomic layer deposition using a precursor comprising (tBuCp)₃M or (BuCp)₃M, where M is a lanthanide or Group III element and Cp is cyclopentadienyl.

16. A method of atomic layer deposition comprising
introducing a first precursor solution having a formula (R₁R₂R₃R₄R₅Cp)₃*M wherein R₁, R₂, R₃, R₄, and R₅ are H or a hydrocarbon having the formula CₙHₘ, wherein n=1 to 10 and m=1 to 2n+1, Cp is cyclopentadienyl and M is a lanthanide or Group III element dissolved in a solvent to a vaporizer;
vaporizing the first precursor solution in the vaporizer;
delivering the vaporized first precursor to a deposition chamber;
forming a monolayer of a metal containing molecule by surface reaction on a substrate;
purging the deposition chamber;
introducing a second precursor comprising an oxygen containing compound to the deposition chamber;
forming one monolayer of a metal oxide film by surface reaction on the substrate; and
repeating the steps to produce a metal oxide film of predetermined thickness on the substrate.

17. The method of claim 16 wherein delivering the vaporized first precursor comprises delivering the first precursor in an ideal square wave form.

18. The method of claim 16 wherein introducing the second precursor comprises delivering the second precursor in an ideal square wave form.

19. The method of claim 16 wherein the vaporizer temperature is between 140° C. and 180° C. and the deposition temperature is between 150° C. and 200° C.

20. The method of claim 19 wherein the vaporizer temperature is 150° C. to 160° C. and the deposition temperature is 150° C.

21. The method of claim 16 wherein the solvent is an alkane, alkene, alkyne, amide, acetate, ether, ester, a hydrocarbon, or mixtures thereof.

22. The method of claim 21 wherein the solvent is oxygen free.

23. The method of claim 16 wherein the second precursor is O₂, O₃, N₂O, NO, CO, CO₂, CH₃OH, C₂H₅OH, an alcohol, an acid, or an oxidant.

24. The method of claim 16 wherein the metal oxide film is Gd₂O₃ or La₂O₃.

25. A method of atomic layer deposition comprising
introducing a first precursor solution having a formula (R₁R₂R₃R₄R₅Cp)₃*M wherein R₁, R₂, R₃, R₄, and R₅ are H or a hydrocarbon having the formula CₙHₘ, wherein n=1 to 10 and m=1 to 2n+1, Cp is cyclopentadienyl and M is a lanthanide or Group III element dissolved in a solvent to a vaporizer;
vaporizing the first precursor solution in the vaporizer;
delivering the vaporized first precursor to a deposition chamber;
forming a monolayer of a metal containing molecule by surface reaction on a substrate;
purging the deposition chamber;
introducing a second precursor comprising an nitrogen containing compound to the deposition chamber;
forming one monolayer of a metal nitride film by surface reaction on the substrate; and
repeating the steps to produce a metal nitride film of predetermined thickness on the substrate.

26. The method of claim 25 wherein delivering the vaporized first precursor comprises delivering the first precursor in an ideal square wave form.

27. The method of claim 25 wherein introducing the second precursor comprises delivering the second precursor in an ideal square wave form.

28. The method of claim 25 wherein second precursor is NH₃, N₂H₄, or an amine.

29. A method of atomic layer deposition comprising
introducing a first precursor solution having a formula (R₁R₂R₃R₄R₅Cp)₃*M wherein R₁, R₂, R₃, R₄, and R₅ are H or a hydrocarbon having the formula CₙHₘ, wherein n=1 to 10 and m=1 to 2n+1, Cp is cyclopentadienyl and M is a lanthanide or Group III element dissolved in a solvent to a vaporizer;
vaporizing the first precursor solution in the vaporizer;
delivering the vaporized first precursor to a deposition chamber;
forming a monolayer of a metal containing molecule by surface reaction on a substrate;
purging the deposition chamber;
introducing a second precursor comprising a reactive reducing compound to the deposition chamber;
forming one monolayer of a metal film by surface reaction on the substrate; and
repeating the steps to produce a metal film of predetermined thickness on the substrate.

30. The method of claim 29 wherein delivering the vaporized first precursor comprises delivering the first precursor in an ideal square wave form.

31. The method of claim 29 wherein introducing the second precursor comprises delivering the second precursor in an ideal square wave form.

32. The method of claim 29 wherein the reducing compound is hydrogen or hydrogen atoms.
